(19) United States
(12) Patent Application Publication
(10) Pub. No.: US 2022/0329088 A1
(43) Pub. Date: Oct. 13, 2022

(54) ENERGY STORAGE SYSTEM

(71) Applicant: Enertek Holdings Pty Ltd, Victoria (AU)

(72) Inventor: Rohan Michael Siebel, Kew, Victoria (AU)

(21) Appl. No.: 17/641,084

(22) PCT Filed: Sep. 8, 2020
(86) PCT No.: PCT/AU2020/050946

§ 371 Date: Mar. 7, 2022

(30) Foreign Application Priority Data
Sep. 9, 2019 (AU) 2019903331
Jul. 15, 2020 (AU) 2020902444

(51) Int. Cl. H02J 7/00; H02B 1/30; H02J 13/00; H05K 5/02; H01M 50/204

(52) U.S. Cl. CPC H02J 7/0042; H02B 1/305; H02J 13/00034; H05K 5/0247; H01M 50/204; H01M 2220/10

(57) ABSTRACT

The invention is directed towards a modular energy storage system for receiving power from a source, storing energy within a storage module, and delivering power to a load. The system includes a master unit containing the storage module for storing energy, and an inverter for receiving AC power and converting to DC power for storage. The system may also include at least one slave unit containing additional storage modules to increase energy storage capacity.

### TECHNICAL FIELD

This invention relates to a modular electrical energy storage system for transforming and/or storing energy from a source such as an external power grid or localised solar generator, and for providing power to a home electrical system.

### BACKGROUND

Household electricity has traditionally been generated at centralised facilities. These conventional generation facilities are often located far away from homes, with power distributed to consumers via a power grid of networked transmission lines. The rate at which this power is charged to the consumer can vary between peak and non-peak times. For example, the cost of power is often less during non-peak times. As such, households can achieve reduced power-bills by purchasing energy during non-peak times and storing it for later use.

Rising societal concerns over pollution from such centralised facilities, and an increased prevalence of demand shortfalls during peak use periods such as heat-waves have led to an increase in the popularity of localised micro-grid systems, wherein electricity is generated at or near where it will be used. An example of this include solar panels installed in homes. The energy generated by solar cells is dependent on the quantity of sunlight, and thus it is desirable for the energy that is generated to be stored for later use.

Accordingly, domestic electrical power storage devices such as various types of batteries have become wide-spread. These existing energy storage devices are often difficult to install and require specialist electricians to fit and commission. This adds additional expenses to the capital costs of the systems themselves, thus reducing the economic advantage offered by the energy storage system. These existing solutions have limited upgradeability, instead requiring the end-user to specify the storage capacity of the system at the time of installation. Additionally, the configuration of existing systems can make it difficult for end-users and specialist electricians alike to troubleshoot the system, resulting in unnecessary exposure to high-voltage internal components. Furthermore, existing storage systems are often aesthetically unsightly and can only be installed in limited locations within the home.

The present invention was conceived with these shortcomings in mind.

### SUMMARY

In a first aspect, the invention provides a modular energy storage system for delivery of AC electrical power to a load, the energy storage system comprising a master unit; the master unit including an inverter, at least one storage module, a circuit breaker, a first junction portion, a second junction portion, and a housing having an interior divided into a first zone and a second zone; with the first zone containing the inverter for converting AC power from an external power source to DC power for storage within the storage module(s); the second zone containing the circuit breaker operatively connected to the first junction portion and the second junction portion; with each of the junction portions being configured to receive a lead-in cable coupling the energy storage system to the external power source and a distribution cable coupling the energy storage system to the load.

In some embodiments, the housing of the master unit may be generally rectangular. The housing may comprise a rear panel with a mounting aperture, through which the housing can be secured to a wall by a fastener. The housing may comprise a top panel configured such that when mounted to a wall, its surface is inclined with respect to the ground. The housing may comprise a forward-facing panel including a separate cover plate for each of the first and second zones. The cover plate for the first zone may incorporate an indicator to display information related to the energy storage system. The cover plate for first zone may be attached to the housing with rearward facing fasteners and the cover plate for the second zone may be removably attached to the housing with forward facing fasteners. In further embodiments, the cover plate of the second zone may include a magnetically tethered flap proving tool-free access to the circuit breaker.

Alternatively, in some embodiments the housing may comprise an integral cover mountable to a backing plate, the cover being a shell having a front panel and side panels and a top and bottom panel integrated therewith. The backing plate may have a stepped profile, the stepped profile providing a first mounting surface for components within the first zone, and a second mounting surface on a parallel plane offset from the first mounting surface, for components within the second zone. The first mounting surface may have a recess for allowing a portion of the inverter to extend outwardly from the housing. The first junction portion may be located on a first side of the housing and the second junction portion located on an opposing second side of the housing. The first and second zones may be selectively sealable such that at least a portion of the second zone can be physically accessed whilst the first zone remains sealed. The first zone may comprise an upper zone and a lower zone. The upper zone may be selectively sealable from the lower zone such that the upper zone can be physically accessed whilst the lower zone remains sealed.

In some embodiments, the energy storage system may further comprise at least one slave unit to provide additional energy storage capacity. The junction portions may provide an operable connection between the master unit and the at least one slave unit for additional energy storage capacity. The operable connection between the master unit and a slave unit may comprise glands to form a waterproof passage for connecting cables.

The slave unit may include at least one additional storage module, a second circuit breaker, a junction region and a casing having an interior divided into a first compartment and a second compartment; with the first compartment containing the additional storage module(s) providing the modular energy storage system with increased energy storage capacity; the second compartment containing the second circuit breaker operatively connected to the junction region; the junction region configured to facilitate an operative connection between the slave unit and the master unit. The first and second compartments of the slave unit may be selectively sealable such that the second compartment can be physically accessed whilst the first compartment remains sealed.

In some embodiments, the slave unit may further include a second junction region, with each of the junction regions configured to provide an operative connection with an additional slave unit in a daisy-chain arrangement. The junction region may be located on a first side of the casing and the second junction region is located on an opposing second side of the casing.

In another aspect, the invention provides a modular electrical cabinet comprising a housing and at least two junction portions; the housing having an interior divided into at least two zones, with each zone being selectively sealable such that a first zone can be physically accessed whilst the other zones remain sealed; the junction portions being located on opposing sides of the housing and configured to facilitate an operable electrical connection between the modular electrical cabinet and at least one of an external power source, a load and an additional similarly configured electrical cabinet.

In a further aspect still, the invention provides a modular energy storage system for delivery of AC electrical power to a load, comprising a main unit for converting AC power to DC power and a separate sub unit for storing DC power; the main unit including an inverter operably connected to two junction portions located on opposing sides of the main unit, the sub unit including a storage module operably connected to two junction regions located on opposing sides of the sub unit, wherein each junction portion is configured to provide an AC connection between the inverter and an external power source and a DC connection with a first of the junction regions of the sub unit, such that AC power received from the external power source is converted by the inverter of the main unit and stored as DC power within the storage module of the sub unit, the sub unit being locatable on either side of the master unit.

The modular energy storage system may further comprise a second sub unit, the second sub unit being operably connected to a second of the junction regions of the first sub unit, the main unit and sub units being connected in a daisy-chain arrangement.

### BRIEF DESCRIPTION OF DRAWINGS

Embodiments of the invention will now be described in further detail below, wherein like reference numerals indicate similar parts throughout the several views. Embodiments are illustrated by way of example, and not by way of limitation, with reference to the accompanying drawings, in which:

FIG. 1a is a perspective view of a master unit of an energy storage system according to one embodiment of the invention.

FIG. 1b is a side view of a master unit of FIG. 1, showing the master unit attached to a wall via a mounting bracket.

FIG. 1c is a front view of the mounting bracket of FIG. 1b.

FIG. 2a is a front view of an intermediate plate of a front panel of the master unit of FIG. 1, showing an access aperture and cover flap in an open position.

FIG. 2b is a front view of the intermediate plate FIG. 2b, showing the cover flap in a closed position.

FIG. 2c is a rear view of the intermediate plate of FIGS. 2a and 2b, showing a tethered connection of the cover flap to the intermediate plate.

FIG. 3 is a front view of the master unit of FIG. 1, with the front panel removed showing internal components positioned within three zones.

FIG. 4a is a front view of an intermediate zone of the master unit of FIG. 1, showing the components located within the intermediate zone and a first and second junction portion.

FIG. 4b is a perspective view of the intermediate zone of FIG. 4a, showing the second junction portion.

FIG. 4c is a front view of the intermediate zone of FIG. 4a, showing the first junction portion.

FIG. 5 is a front view of the energy storage system according to one embodiment of the invention, showing a slave unit connected to the master unit.

FIG. 6 is a perspective view of the slave unit of FIG. 5, showing an exterior casing and junction region.

FIG. 7 is a front view of the slave unit of FIG. 5, with the front panel removed showing internal components positioned within three compartments.

FIG. 8 is a front view of the energy storage system according to one embodiment, showing two slave units connected to the master unit.

FIG. 9 is a front perspective view of a main unit of an energy storage system according to an embodiment of the invention, showing a housing comprising a backing plate and a cover.

FIG. 10 is a front view of the main unit of FIG. 9, with the cover of the housing removed showing internal components positioned within three zones.

FIG. 11 is a front perspective view of the backing plate of the housing of the main unit of FIG. 9, showing a stepped profile.

FIG. 12 is an internal perspective view of the cover of the housing of the main unit of FIG. 9, illustrating a peripheral lip configured to sit flush against the backing plate.

FIG. 13 is a top perspective view of a mounting plate for mounting the main unit of FIG. 9 to a wall, showing protruding engagement members.

FIG. 14 is a rear perspective view of the main unit of FIG. 9, showing the mounting plate attached to the backing plate.

FIG. 15 is a front perspective view of the main unit of FIG. 9, showing an access door in an open position revealing a removeable cassette within the housing.

FIG. 16 is a perspective view of the removeable cassette of FIG. 15.

FIG. 17 is a front perspective view of the energy storage system according to one embodiment of the invention, showing a sub unit connected to the main unit.

FIG. 18 is a front view of the energy storage system according to one embodiment of the invention, showing three sub units connected to the main unit.

FIG. 19 is a front perspective view of the sub unit of FIGS. 17 and 18, showing an exterior casing comprising a backing plate and a cover.

FIG. 20 is a side perspective view of the sub unit of FIG. 19, with the cover of the casing removed showing internal components positioned within three compartments.

FIG. 21 is a front perspective view of the sub unit of FIG. 19, showing an access door in an open position revealing a removeable cassette within the casing.

FIG. 22 is a rear perspective view of the energy storage system of FIG. 17, showing a guide plate used to correctly position the mounting bracket of the sub unit.

FIG. 23 is a rear perspective view of the energy storage system of FIG. 22, showing an second guide plate used to correctly position the mounting plate of an additional sub unit.

### DETAILED DESCRIPTION

In the following detailed description, reference is made to accompanying drawings which form a part of the detailed description. It will be readily understood that the aspects of the present disclosure, as generally described herein and illustrated in the drawings may be arranged, substituted, combined, separated and designed in a wide variety of different configurations, all of which are contemplated in this disclosure.

Unless defined otherwise, all technical and scientific terms used herein have the same meaning as commonly understood by one of ordinary skill in the art to which this invention belongs. Although any methods and materials similar or equivalent to those described herein can also be used in the practice or testing of the present invention, a limited number of the example methods and materials are described herein.

The embodiment of the energy storage system 1 shown in the Figures is suitable for providing power to a home electrical system. It is understood, however, that other larger implementations can be used for other industrial applications.

In general terms, the modular energy storage system shown in the Figures comprises a master unit 10 which can be connected to several slave units for additional battery storage capacity. As is described in more detail below, the master unit is divided into a top compartment (first zone 11) and a bottom compartment (second zone 13), with a separating zone (intermediate zone 12) in the middle. This arrangement is an important feature of the system. The bottom compartment contains the battery modules for storing the energy. The top compartment contains an inverter, which converts DC electricity generated by an external energy source (such as solar panels, although other sources such as wind power, and geothermal power are also possible) into AC. The AC energy may be transferred to the wider external power grid or used directly in a house (or other building).

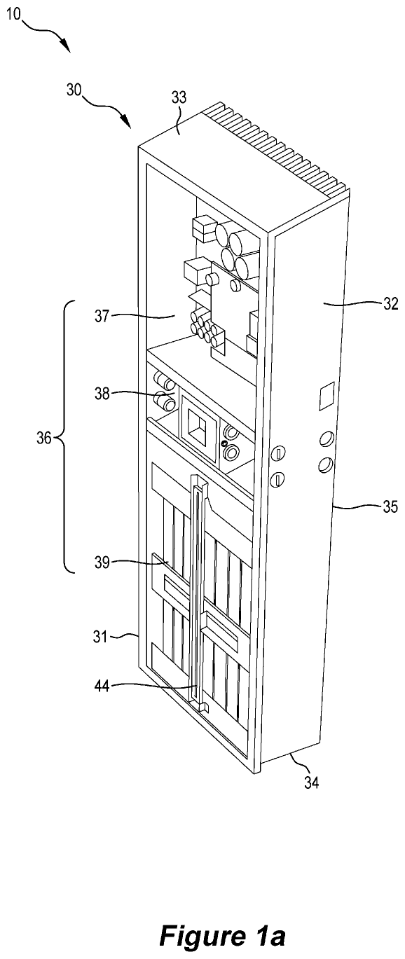

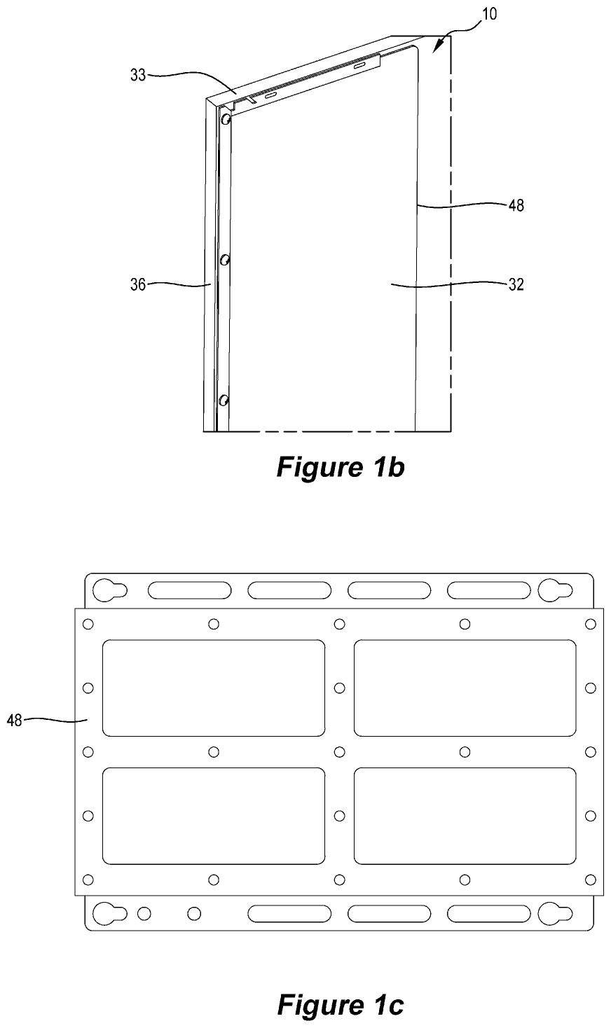

With reference to FIGS. 1a-1c the electrical components of the master unit 10 are contained within a housing 30. The housing 30 is substantially rectangular, comprising first 31 and second 32 side panels, a top panel 33, a bottom panel 34, a rear panel 35 and a front panel 36. Each of the panels 31-36 is made from a resilient material. The material can be a metal. FIG. 1a shows an embodiment where the master unit 10 is mounted in a vertical orientation. Limitations in the availability of horizontal wall-space of typical homes mean that a vertical orientation is preferred. However, it is understood that other mounting orientations are also contemplated. Top panel 33 provides an inclined surface with respect to the ground. This reduces the possibility of dust or dirt gathering on the top plate and promotes any water that may fall upon the top of the master unit 10 to disperse. Similarly, tradesman and homeowners will be dissuaded from leaving objects to rest upon the top surface. FIG. 1b shows the housing 30 mounted to a wall of a home in a conventional manner with the aid of a mounting bracket 48. The front panel 36 includes removable upper 37 and lower 39 plates. Upper plate 37 is disposed near the top of the unit master unit 10, with lower plate 39 disposed near the base of the master unit 10. As shown in FIG. 1a, the upper 37 and lower 39 plates are rectangular, extending across a complete width of the master unit from a first side to a second side. The upper 37 and lower 39 plates are removably secured to the housing 30 via rearward facing fasteners such as screws. This fastening arrangement provides an aesthetically clean visage to the front of the panel, whilst also improving the tamper-proofness of the master unit 10. An LED indicator 44 provides the user with information regarding the status of the energy storage system 1. The information displayed can be selected from many parameters, including energy storage level, system operative mode and similar. The LED indicator provides a quick and easy method of displaying important information to the user, whilst eliminating the need for the user to cycle through numerous menus on a small display screen or similar as is typical in other systems. Whilst LED indicator 44 is illustrated in FIG. 1a as being positioned on the lower plate 39, it is understood that the LED indicator 44 can be in any visible position on the housing 30. Positioning on the front panel 36 is preferable, as it provides the most visible position. A rectangular intermediate plate 38 is positioned between the upper 37 and lower 39 plates. The intermediate plate 38 is removably secured to the housing 30 via forward facing fasteners such as screws. This fastening arrangement provides simple and quick access to electrical components contained beneath the intermediate plate 38 within the master unit 10. As shown in FIG. 1c, mounting bracket 48 is rectangular, with a width less than that of the master unit. As such, when the master unit 10 is viewed from the front, the mounting bracket 48 is not visible. Mounting bracket 48 has a top hat profile, with lower outer portions and a raised central portion. The rear panel 35 of the master unit 10 is spaced from the wall by a distance equal to that of the height of the central portion of the top hat of the mounting bracket 48. The mounting bracket 48 includes a plurality of pre-cut slots and apertures on the outer portion, through which the rear panel 35 of the master unit 10 is securely attached. A plurality of spaced holes disposed on the central portion of the top hat provide means of securing the mounting bracket 48 to the wall.

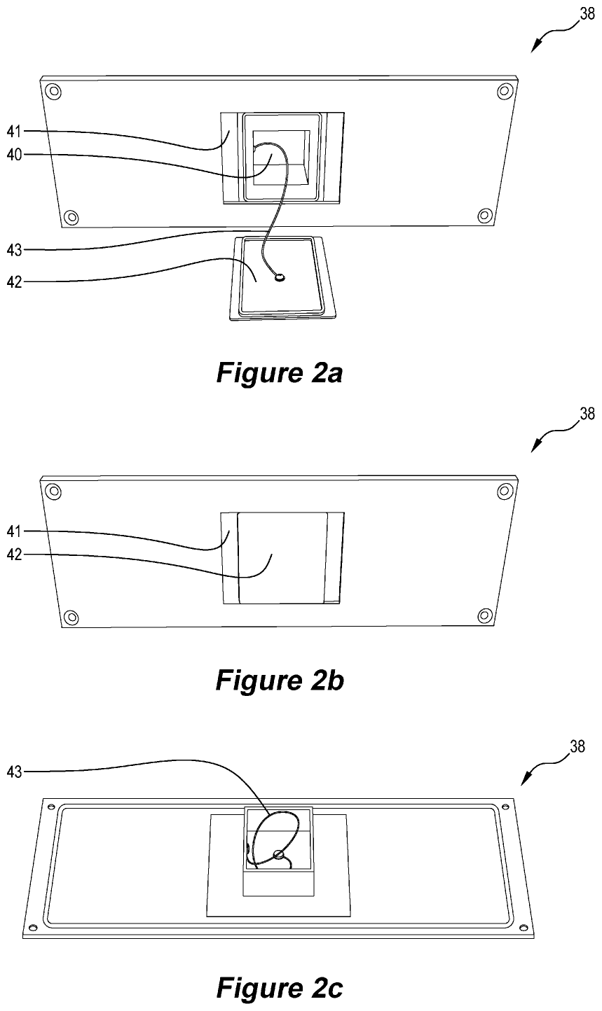

Referring now to FIG. 2a, a square access aperture 40 is centrally disposed on the intermediate plate 38. Cover flap 42 is attached to the intermediate plate 38 via a tethered connection 43. A recess 41 surrounds the aperture 40 and is sized to receive cover flap 42. With the cover flap 43 in an open position, the access aperture 40 enables quick tool-free access to a circuit breaker box 16 positioned within the mater unit 10. With reference to FIG. 2b, cover flap 42 may be held in a closed position within the recess 41 via a magnetic connection. With the cover flap 42 in the closed position, the housing 30 is watertight. With reference to FIG. 2c, an end of the tethered connection is secured on the non-forward-facing side of the intermediate plate 38. The tethered connection ensures that the cover flap 42 does not get misplaced or lost when it is necessary to gain access to the circuit breaker box 16.

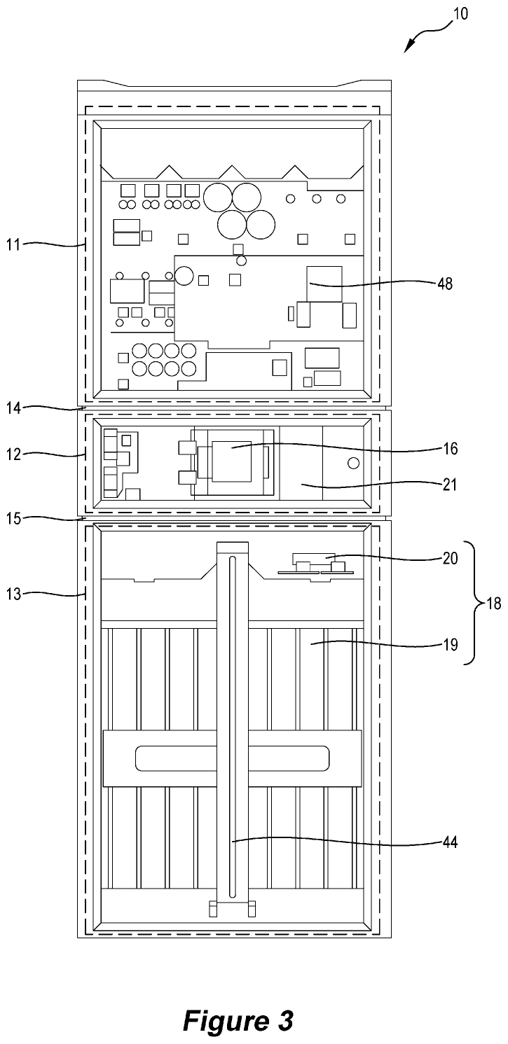

Various electrical components can be conventionally mounted within master unit 10 and are shown and described in detail with reference to FIG. 3. A first internal divider 14 extends horizontally across the width of the housing 30 from the first side panel 31 to the second side panel 32, defining a first 11 and second 12 interior zone within the master unit 10. Each of the interior zones 11 and 12 are selectably sealable such that physical access to one of the zones 11 or 12 through front panel 36 does not require or provide physical access to the other zone. As illustrated in FIG. 3, a second internal divider 15 extends horizontally from the first side panel 31 to the second side panel 32 effectively forms a third zone 13.

The first zone 11 forms an upper zone positioned near the top of the master unit 10. Upper zone 11 extends in width between the first and second side panels 32, in height between the top panel 33 and the first internal divider 14, and in depth between the rear panel 35 to front panel 36. An inverter 17, located within the upper zone 11, is configured to convert generated AC electricity to storable DC electricity, and storable DC electricity to useable AC electricity. Access to upper zone 11 is provided to the user and/or tradesmen by removing upper plate 37 from front panel 36.

The third zone 13 forms a lower zone positioned near the bottom of the master unit. Lower zone 13 extends in width between the first and second side panels 32, in height between the bottom panel 34 and the second internal divider 15, and in depth between the rear panel 35 to front panel 36. An energy storage module 18 is located within the lower zone 13. As shown, the energy storage module 18 is a battery bank. The battery bank 18 comprises of a plurality of battery cells 19 and a battery management system 20. Access to lower zone 13 is provided by removing lower plate 38.

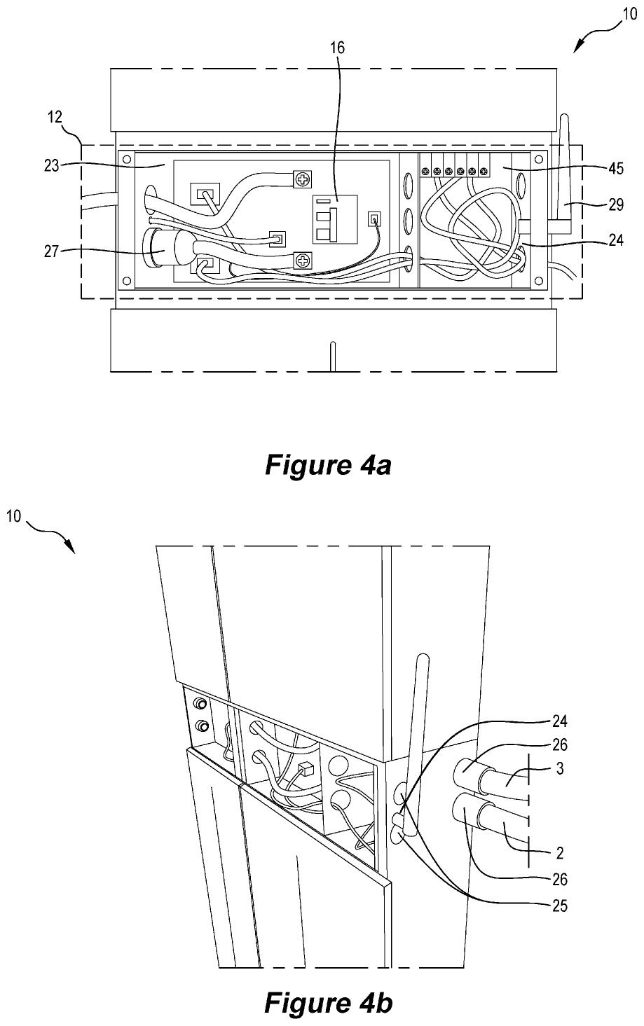

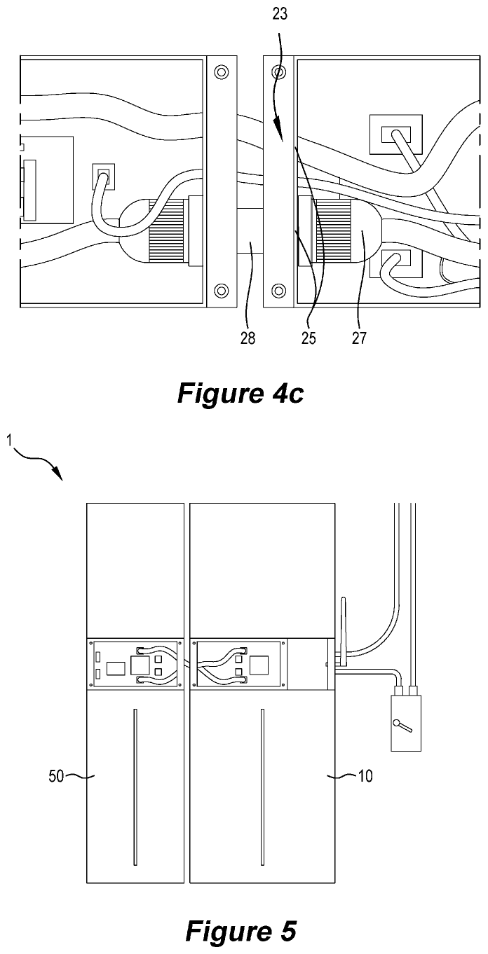

The second zone 12 is positioned between the upper zone 11 and lower zone 13. Intermediate zone 12 extends in width between the first and second side panels 32, in height between the first internal divider 14 and the second internal divider 15, and in depth between the rear panel 35 to front panel 36. The circuit breaker box 16 is located within the intermediate zone 12. The intermediate zone 12 also contains a controller 21 which controls the operation of the energy storage system 1, and a communications module 22 (not shown). Communications module 22 can include 4G and Bluetooth connections, enabling wireless and remote access to the controller 21, providing a user with a simple means for troubleshooting and accessing detailed unit status, as well as selecting the information to be displayed via the LED status indicator 44. Access to a portion of the intermediate zone 12 corresponding to the position of the circuit breaker box 16 is also provided through aperture 40 by removing the cover flap 42 from recess 41. As shown in FIG. 4, in some embodiments, the communications module 22 includes an external antenna 29 which protrudes through one of the side panels 31,32.

With reference to FIGS. 4a-c, a first junction portion 23 is positioned within the intermediate zone 12, at an end adjacent to the first side panel 31. A second junction portion 24 is positioned at an opposing end, adjacent to the second side panel 32. Each of the junction portions 23, 24 are configured to provide an AC connection between the master unit 10 and an external power source 5, and a AC connection between the master unit 10 and a load 4. Each of the junction portions 23, 24 is also configured to provide a DC connection between the master unit 10 and a slave unit 50.

Each junction portion 23, 24 is comprised of four circular bores in the side panels 31, 32. The circular bores are arranged in a square array, with a forward pair of bores 25 vertically aligned adjacent to the front of the housing 30, and a rear pair of bores 26 vertically aligned adjacent to the rear of the housing 30. Cable glands 27 of a conventional type are received within and secured to abut each bore to provide a releasable, water resistant cabled connection into and out of the master unit 10. As illustrated, each of the pairs of circular bores 25, 26 are approximately 25 mm in diameter, however both larger (for example 50 mm) and small (for example 10 mm) are also contemplated. By providing the junction portions 31, 32 on either side of the housing 30, the master unit 10 can be installed the AC connection to the master unit 10 can be on either side. This contrasts with traditional solutions where the AC connection is provided on one side only. This is advantageous, as it enables the master unit 10 to be installed to the left and to the right of a home switchboard, whilst installation of traditional systems can result in unsightly conduit cable extending around the outside of said traditional system if the AC connection is on the far side in relation to the home switchboard.

With reference to FIG. 4b, each rear pair of bores 26 provides the AC connection between the master unit 10 and the external power source 5 (not shown) and load 4 (not shown). The AC connection of each of the rear pair of bores 26 comprises a lead in cable 2 that connects the master unit 10 to an external power source 5. The external power source 5 is a conventional power generation facility which distributes power to the home via an external power grid. In an energy harvesting mode, AC power from the external power source 5 is led to the energy storage system 1 via lead in cable 2, which terminates at circuit breaker box 16. AC power then flows to inverter 17 which converts the AC power to DC power. The DC power then flows to the battery bank 18 where the power is stored as chemical energy within the plurality of battery cells 19.

The energy storage system 1 provides AC power to the load 4. The load 4 is a home electrical system for example which can include several typical house-hold appliances requiring power. In an energy deployment mode, energy stored within the battery bank 18 flows to inverter 17 which converts the DC power to AC power. A distribution cable 3, which originates at the circuit break box 16, exits the master unit 10 via the second pair of bores 26 and connects the energy storage system 1 to the load 4. An advantage of this arrangement is that user can obtain power from the external power source 5 at non-peak periods associated with reduced costs and store the energy within the battery bank 18 for later use. This results in a reduced power bill, as the user is not reliant on obtaining power from the external power source 5 during peak periods (associated with higher power costs) and can instead use the power stored within the battery bank 18.

The lead in cable 2 can also connect the master unit 10 to additional power sources 6. The additional power sources 6 can include conventional solar panels or wind turbines that are installed at the home. Power from these additional sources 6 can be stored within the battery bank 18 in the same manner as power from the external power source 5. Power generation from additional power sources 6 is often unstable, in that it can vary throughout the day. For example, solar cells require sunlight to generate power and wind turbines require wind. As such, an advantage of the energy storage system 1 is that energy generated by these systems 6 can be stored in battery bank 18 and used to power load 4 when demand requires. This results in a reduced requirement for power from the external energy source 5, further reducing the costs of powering the home.

With reference to FIG. 4c, each front pair of bores 25 provides the DC connection between the master unit 10 and additional slave units 50. The DC connection of each of the front pair of bores 25 comprises a tubular conduit 28 that is received and secured within cable glands 27. Each of the cable glands 27 are of a conventional design and can include a locknut which is attached to one threaded end of a gland body, with a gland dome attached to an opposing threaded end of the gland body. In reference to the DC connection, the locknut of each of the cable glands 27 is located externally of the housing 30, with the gland body and cable glands intruding into the intermediate zone 13. In combination with the tubular conduit 28, the front pair of bores 25 of each junction portion 23,24 provide a water-proof passage for cables to pass between the master unit 10 and the slave unit 50.

Returning to FIG. 4a, a rear mounting aperture 45 is disposed on the rear panel 35 within the intermediate zone 12. The rear mounting aperture provides a method of securing the master unit 10 to a wall via conventional means such as a bolt. Rear mounting aperture 45 is only accessible when the intermediate plate 38 is removed, it is otherwise hidden from view. This provides an anti-tamper measure, reducing the likelihood of the master unit 10 being stolen or removed from the wall by vandals.

FIG. 5 shows one embodiment of the energy storage system 1 comprising one slave unit 50 connected to the master unit 10. Slave unit 50 is configured in a similar manner to that described herein in relation to the master unit 10. Operation of slave unit 50 is controlled by the controller 21 within the master unit 10

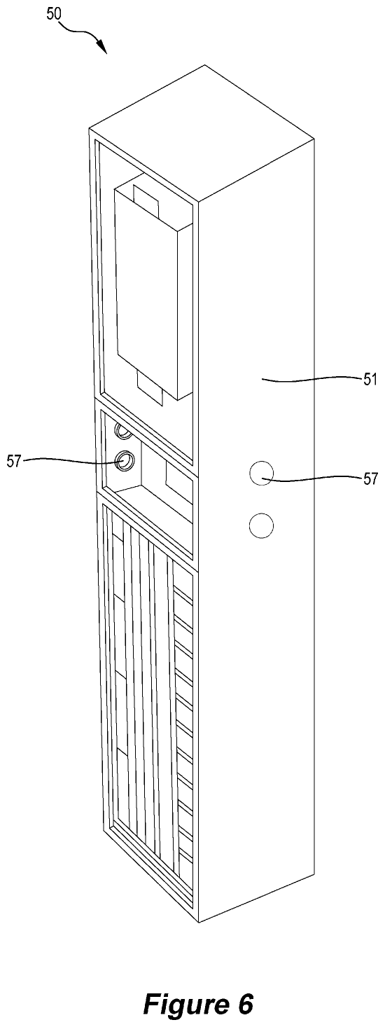

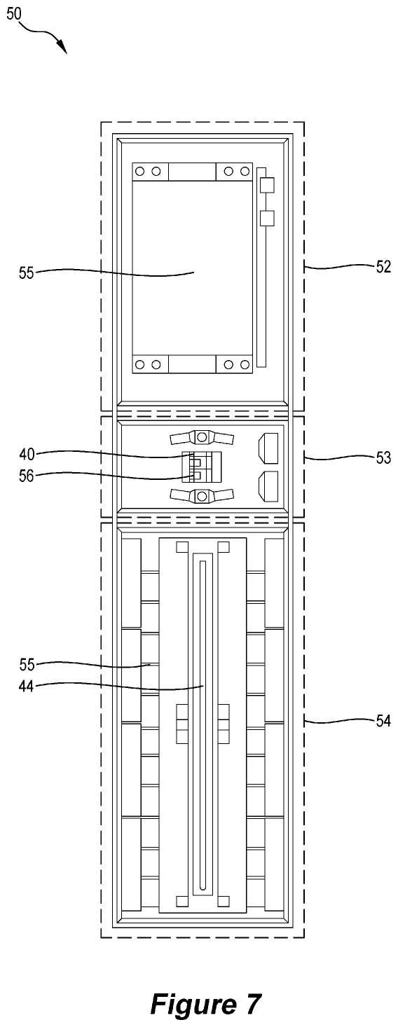

As shown in FIGS. 6 and 7, within a casing 51 the slave unit 50 comprises an upper compartment 52, an intermediate compartment 53 and lower compartment 54. The upper 52, and lower 54 compartments of the slave unit 50 contain additional energy storage modules 55. Energy storage modules 55 are battery banks that provide additional storage capacity to the battery banks 18 within the master unit 10. As such, the user can increase the energy storage capacity of their energy storage system 1 by fitting one or more slave units 50 to the master unit 10. As illustrated in FIG. 7, the casing of the slave unit 50 also features a LED status indicator 44.

Within the intermediate zone 53 is a circuit breaker 56. Circuit breaker 56 is accessible to the user through the casing 51 in the same manner in which circuit breaker 18 of the master unit is accessible to the user via cover flap 42 and aperture 40. The intermediate zone 53 of the slave unit 50 further comprises a pair of junction regions 57, disposed at opposing ends of the intermediate zone 53. Each of the junction regions 57 comprises a pair of glands 47 positioned within a pair of bores 58, the glands 47 configured to receive tubular conduits 28. The pair of bores 58 are positioned to correspond to the front bores 25 of the master unit 10. Hence, each of the junction regions 57 provide an operable connection between the master unit 10 and the slave unit 50. In the same manner, each of the junction regions 57 can be adapted to provide an operable connection to an additional slave unit 50.

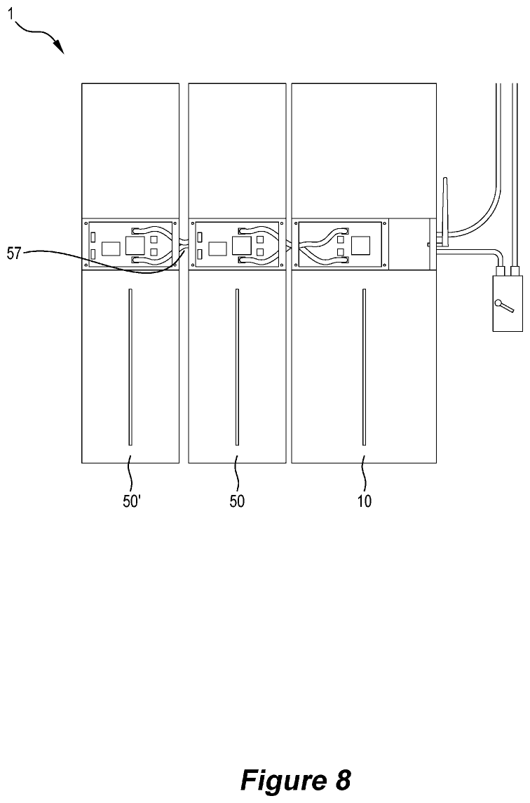

FIG. 8 shows an embodiment of the energy storage system 1 where an additional slave unit 50 is operatively connected to the first slave unit via the free junction region 57. The modular nature of the energy storage system 1 provides upgradeability, enabling several additional slave units 50 to be operatively connected in a daisy-chain arrangement to increase the storage capacity of the system. This provides the ability for a user to increase their storage capacity should their energy needs change, and to spread out the cost of capital investment over separate installations and purchases. Summarily, it is to be understood that the internal arrangements of the master 10 and slave 50 units of the modular energy storage system 1, in particular the dividing of said units 10,50 into selectively sealable compartments and zones, provide several advantages and cost savings to a home user. For example, installation of the modular energy storage system 1 is fast and requires little expertise or technical know-how, because the units 10, 50 making up the system 1 can easily be connected together in a modular fashion, with the necessary electrical components pre-installed and connected within the respective housings 30 and 51. Similarly, user access and exposure to the interior components can be limited to specific zones, reducing unnecessary user exposure and risk to potentially dangerous components or voltages, without otherwise compromising safety and ease of access to safety devices and user serviceable parts such as circuit breakers 16 and 56.

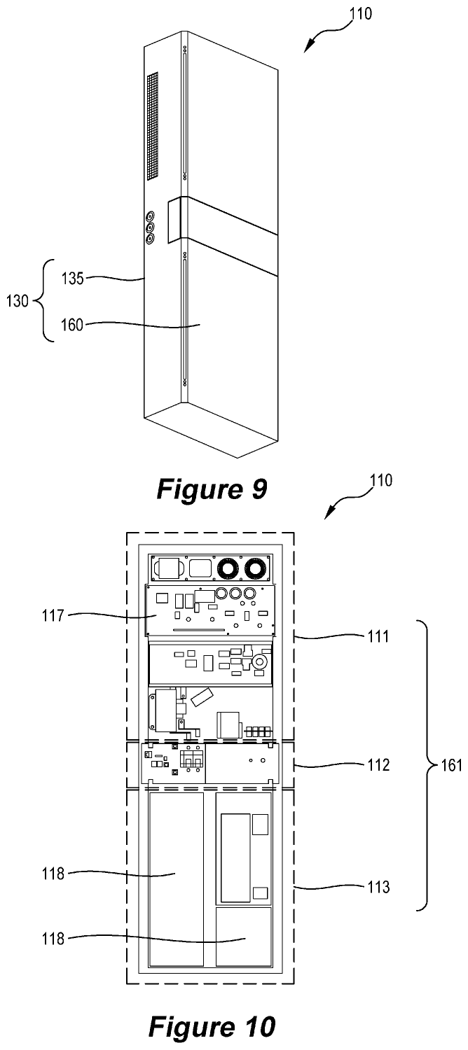

An alternative embodiment of the invention, in the form of energy storage system 101, will now be described with reference to FIGS. 9 to 21. For clarity, similar components and functional analogues will be described using similar terminology and numerical references.

Energy storage system 101 comprises a main unit 110 and, optionally, one or more sub units 150. Referring first to FIGS. 9 and 10, the main unit 110 is accommodated within a housing 130. The housing 130 is rectangular in profile and comprises a unitary cover 160 that is removably attached to a backing plate 135. An interior 161 of the housing 130 between the backing plate 135 and the cover 160 includes an upper zone 111 and a lower zone 113, with an intermediate zone 112 positioned therebetween. An inverter 117 is mounted to the backing plate 135 within the upper zone 111, whilst an energy storage module 118 is mounted to the backing plate 135 within the lower zone 113. When the cover 160 is attached to the backing plate 135, and the inverter 117 is fixed within the upper zone 111, the interior 161 is watertight.

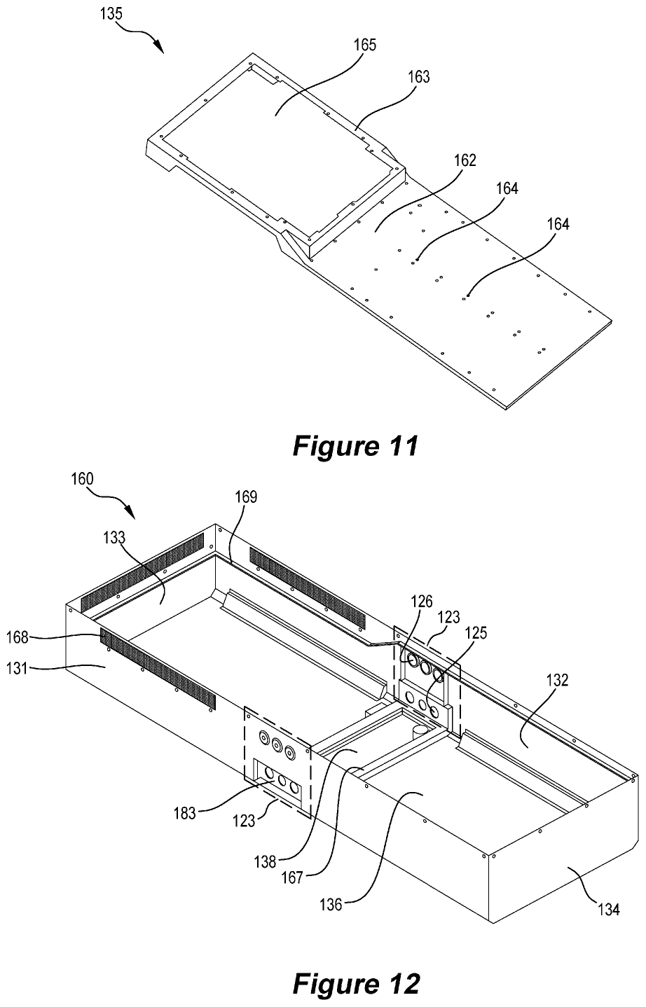

As shown in FIG. 11, the backing plate 135 has a stepped profile, comprising a first mounting surface 162 in the form of a flat plate, and a second mounting surface 163, positioned on a plane parallel to, but spaced from, the first mounting surface 162 via a shoulder. The first mounting surface 162 includes a plurality of mounting holes 164 for mounting the energy storage module 118 thereto. The second mounting surface 163 includes an outer perimeter that forms a portion of a rear boundary to the upper zone 111 and a rectangular cavity 165 that is adapted to receive the inverter unit 117. The inverter 117 sits flush against the outer perimeter of the second mounting surface 163, whilst a rear portion 166 (shown in FIG. 14), extends outwardly from the housing 130 behind the backing plate 135. As the rear portion 166 of the inverter 117 is outside of the sealed interior 161, it is in communication with air from the external environment. Accordingly, heat from a heat sink of the rear portion 166 dissipates to the external environment. The stepped profile of the backing plate 135 facilitates this.

The cover 160 has a shell-like design, with first 131 and second 132 side panels, a top panel 133 and a bottom panel 134 connected to or extending from front panels 136. The cover 160 is shown in FIG. 12. The front panel 136 seals the upper 111 and lower 113 zones of the housing 130, such that these zones are inaccessible to the home user. If necessary, a technician can access these zones by detaching the cover 160 from the backing plate 135. Due to the integrated design, the cover 160 can be attached and removed from the backing plate 135 in a single action. This provides fast assembly and rapid disassembly for repair and maintenance. An aperture 167 extends horizontally across the front panel and is positioned to correspond with the intermediate zone 112. 112. In FIG. 12, the aperture 167 is selectively sealed by an access door 138.

The side panels 131 and 132 and top panel 133 extend behind the backing plate 135, so as to partially enclose the rear portion 166 of the inverter 117 and protect it from water ingress. Ventilation holes 168 within the side panels 131 and 132 maintain fluid communication between the rear portion 166 of the inverter 117 and the external environment.

An internally protruding lip 169 runs around a periphery of the cover 160 and is configured to sit flush against the backing plate 135. As can be clearly seen in FIG. 12, the lip 169 includes a stepped profile, such that both the first mounting surface 162 and the second mounting surface 163 of the backing plate 135 are flush with the backing plate 135. A rubber seal 170 (not illustrated) can be run along the lip 169, to aid in providing the watertight seal between the backing plate 135 and cover 160.

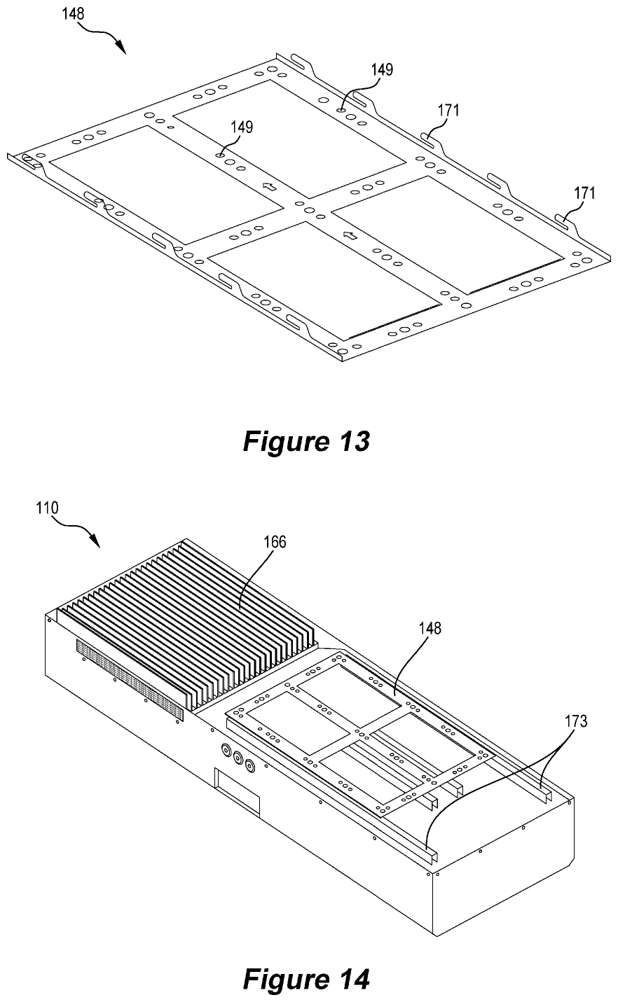

The master unit 110 is mounted to a wall via a mounting plate 148. As shown in FIG. 13, mounting plate 148 is of a low profile rectangular design, and includes a plurality of holes 149 through which fasteners are inserted to fix the mounting plate 148 to the wall. Engagement members 171 protrude from one side of the plate 148. The engagement members 171 are teeth configured to be received within elongate slots 172 (not shown) of the housing 130. The slots 172 are disposed within elongate rails 173 (see FIG. 14), which protrude outwardly from a rear face of the backing plate 135. The elongate rails 173 act as a spacer, ensuring a minimum gap is maintained between the main unit 110 and the wall that it is mounted to.

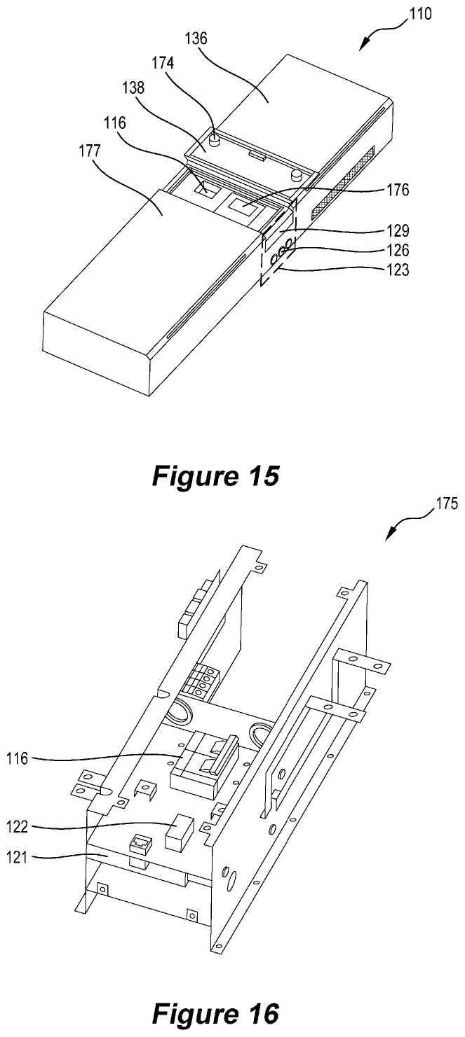

The access door 138 is moveable between a closed position (as shown in FIGS. 9 and 12), to an open position, as shown in FIG. 15. The access door 138 includes a pair of internally mounted magnets 174. When the access door 138 is in a closed position the magnets 174 are brought into contact with a magnetic surface within the interior 161 of the housing 130, magnetically sealing the access door 138 closed. The access door 138 has a hinge on its upper edge so as to open upwardly with respect to the housing 130. With the access door 138 in a fully open position, a third internal magnet, shown in the illustrated embodiment as being located between the magnets 174, provides a magnetic connection between the access door 138 to the front panel 136, such that the door 138 abuts the front panel 136.

Opening the access door 138 provides a user with access to components the intermediate zone 112 of the interior 161. These components are mounted to a removable cassette 175. The removeable cassette 175 is secured to the backing plate 135. With reference to FIG. 16, the cassette 175 is a frame that has a circuit breaker 116 mounted thereto. The circuit breaker 116 is operably connected to the inverter 117 and the energy storage module 118. A controller 121, shown in the illustrated embodiment as a PCB board and a communications module 122 are also mounted to the cassette 175, beneath a masking plate 177. The masking plate 177 is screwed onto a front of the cassette 175, such that when the access door 138 is opened, only the circuit breaker 116 and a touchscreen 176 are visible and accessible to the user. The touchscreen 176 is mounted to the masking plate 177, and provides status information of the unit 130 to a user and can also be used by an installer for diagnostic and maintenance purposes. The controller 121 is operably connected to the inverter 117, battery management system and communications module 122. Diagnostic ports allow a technician to perform diagnostics on the inverter 117, battery management system and communications module 122, via the controller 121, without removal of the masking plate 188. Removal of the masking plate 177 requires specialist tools, thus restricting user access to the controller 121 and communications module 122. The masking plate 177 is made from a magnetic material, providing the contact surface that forms the magnetic seal with the magnets 174.

The main unit 110 includes two junction portions 123 located on opposing sides of the intermediate zone 112, one of which is indicated in dotted outline in FIG. 15. Each junction portion 123 is operably connected to the circuit breaker 116 and is configured to receive AC connection cables, and communication cables. The AC connection cables connect the main unit 110 with an external power source from which the main unit 130 can harvest power. The AC connection cables also connect the main unit 110 with an external load to which the main unit 130 can deliver power. The AC connection cables are insertable into the interior 161 via bores 126 of the junction portions 123. As best shown FIG. 12, bores 126 are disposed within side panels 131 and 132 of the cover 160. Bores 126 are vertically aligned and are positioned adjacent to the lip 169 of the cover 160, toward a rear of the housing 130. Accordingly, when the main unit 130 is mounted to a wall, the AC connection cables can be mounted flush against to the wall.

Each junction portion 123 also includes a rectangular recess 183. The rectangular recess 183 is disposed within the side panels 131, 132 towards a front of the main unit 130. The recess 183 provides a location for an external antenna 129 (shown in FIG. 15) to be placed. The external antenna 129 is accommodated within a rectangular enclosure that is configured to fit within the recess 183. This maintains a slimline external profile of the main unit 110, without an unsightly externally protruding antenna.

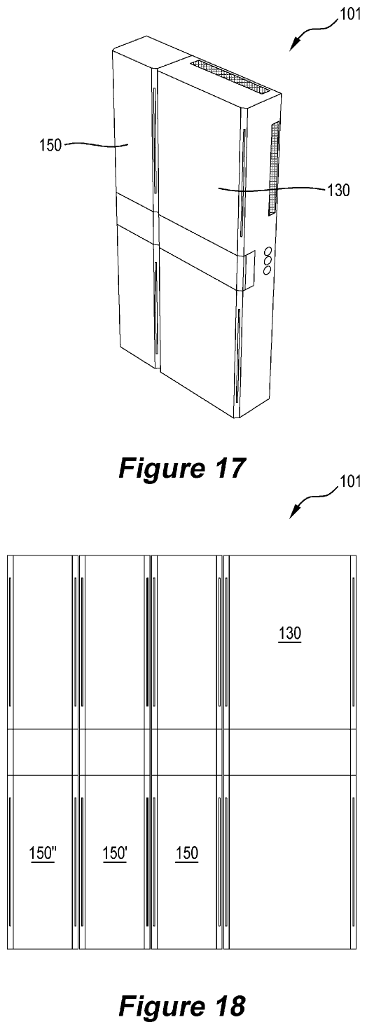

Should additional energy storage capacity be needed, one or more sub units 150 can be connected to a side of the main unit 110 in a daisy-chain arrangement, as shown in FIGS. 17 and 18.

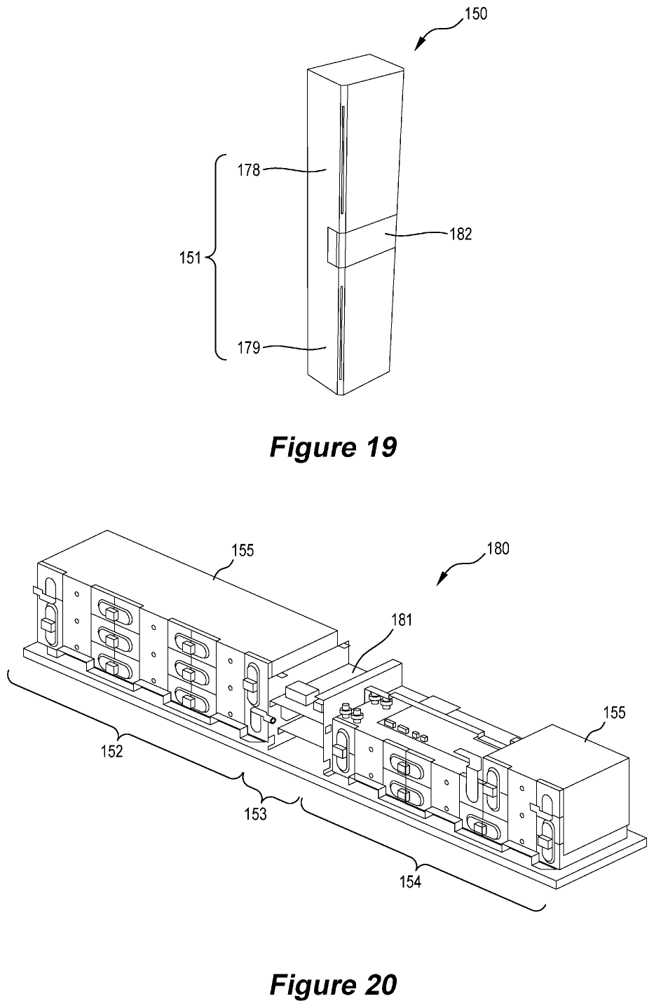

Referring now to FIGS. 19 and 20, the sub unit 150 comprises a plurality of additional storage modules 155, accommodated within a rectangular casing 151. The casing 151 of the sub unit 150 is configured like the housing 130 of the main unit 110, comprising an integral cover 178, that is removably attachable to a backing plate 179.

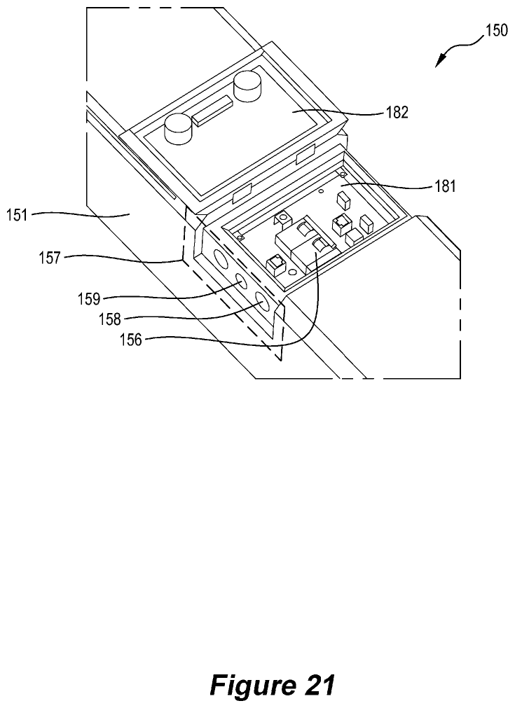

An interior 180 of the casing 151 includes an upper compartment 152 and a lower compartment 154, within which the storage modules 155 are attached to the backing plate 179. An intermediate compartment 153 is located between the upper 152 and lower 154 compartments. The intermediate compartment 153 contains a removable cassette 181, which can be assessed by opening an access door 182. Best shown in FIG. 21, the removable cassette 181 includes a circuit breaker 156, that is operably connected to the additional storage modules 155. When a user opens access door 182, only components located within the intermediate compartment 153 are accessible. The upper 152 and lower 154 compartments remain sealed from the user.

The sub unit 150 includes two junction regions 157 disposed at opposing ends of the intermediate compartment 153. One of the junction regions 157 is indicated in dotted outline in FIG. 21. Each junction region 157 is operably connected to the circuit breaker 156 and provides a DC connection between the sub unit 150 and the main unit 110. The DC connection between the sub unit 150 and the main unit 110 is established by at least two glands 128 (not shown). The glands 128 are insertable into either side of casing 151 via one of apertures 158, located within junction regions 157, together providing a watertight seal. The apertures 158 are vertically aligned and are positioned toward a front of the casing 151. A further aperture 159, illustrated in the Figures between apertures 158, provides passage for communication and earthing cables, between the sub unit 150 and the main unit 110. The junction regions 157 are disposed on either side of the intermediate compartment 153, such that the sub unit 150 can be located to either side of the main unit 110.

Returning now to FIG. 12, junction portions 123 of the main unit 130 also include vertically aligned apertures 125. The apertures 125 are configured to receive glands 128 to establish the DC connection with the sub unit 150. The apertures 125 are provided within the rectangular recess 183 of the side panels 131 and 132. When the antenna 129 is received within recess 183, apertures 125 are covered up and inaccessible.

Accordingly, the antenna 129 must be fitted within the recess 183 of the junction portion 123 that is not being used to connect to a sub unit 150. For example, in the embodiments shown in FIGS. 17 and 18, the antenna 129 is accommodated within a junction zone 123 on a right-hand side of the main unit 130, such that the sub unit 150 can be connected to the main unit 150 through a junction zone 123 on a left-hand side of the main unit 130.

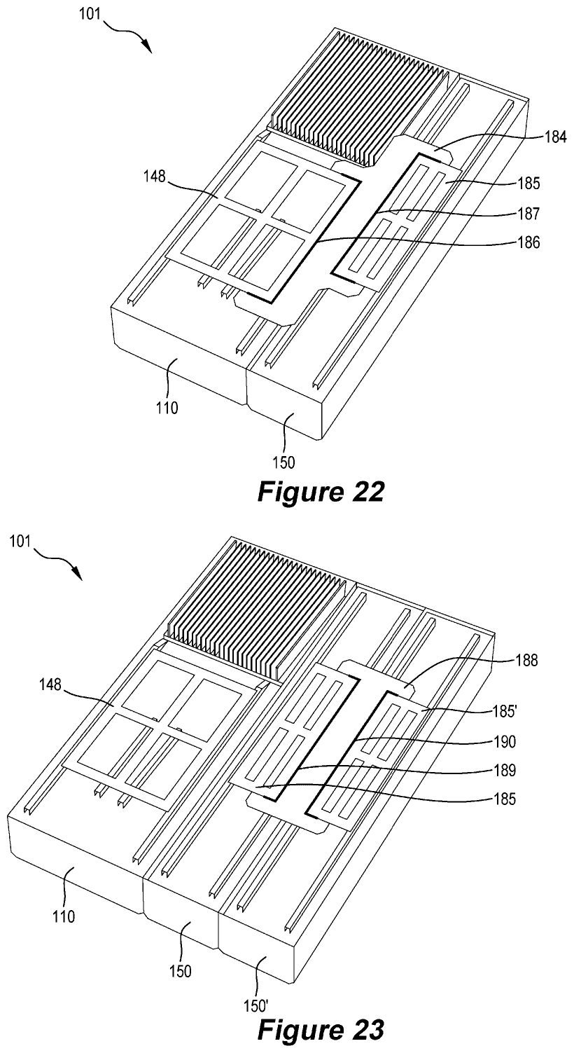

When installing sub unit 150, it is important that it be located correctly with respect to the main unit 110. To this end, a guide plate 184 is provided. Illustrated in FIG. 22, guide plate 184 assists the installer to correctly position a mounting bracket 185 of the sub unit 150 relative to the mounting plate 148 of the main unit 110. Guide plate 184 includes a first receiving portion 186 defined by a first pair of spaced arms extending from a side of a central web portion, and a second receiving portion 187 defined by a second pair of spaced arms extending from an opposing side of the central web portion, the second pair of spaced arms 187 being offset from the first pair of arms 186. During installation, the installer places the guide plate 184 against the wall, adjacent to the mounting plate 148 of the main unit 110, such that the first receiving portion 186 abuts against upper, lower and side edges of the mounting bracket 148. The installer then positions the mounting bracket 185 of the sub unit 110 against the second receiving portion 187 and fixes it to the wall.

Turning to FIG. 23, a second guide plate 188 is shown. Guide plate 188 aids an installer with correctly positioning a mounting bracket 185′ of an additional sub unit 150′, relative to an existing sub unit 150. Guide plate 188 is a plate in the shape of an I Beam, having parallel upper and lower flange sections spaced apart by a central web. A first receiving portion 189 is defined between the upper and lower flanges and a side of the central web, whilst a second receiving portion 190 is defined between the upper and lower flanges on an opposing side of the central web. During installation, the installer places the guide plate 188 against the wall, such that the first receiving portion 189 abuts around the mounting bracket 185 of the existing sub unit 150. The installer then positions the mounting bracket 185′ of the additional sub unit 150′ within the second receiving portion 190, fixing it to the wall.

Summarily, it is to be understood that the internal arrangements of each of the main 110 and sub 150 units of the energy storage system 101, in particular the dividing of said units 110, 150 into sealable compartments and zones, provide several advantages and cost savings to a home user. For example, installation of the modular energy storage system 101 is fast and requires little expertise or technical know-how, because the units 110, 150 making up the system 101 can easily be connected in a modular fashion, with the necessary electrical components pre-installed and connected within the respective housings 130 and 151. Similarly, user access and exposure to the interior components is limited to selected components within the intermediate zone, reducing unnecessary user exposure and risk to potentially dangerous components or voltages, without otherwise compromising safety and ease of access to safety devices and user serviceable parts such as circuit breakers 116 and 156.

It is to be understood that, if any prior art publication is referred to herein, such reference does not constitute an admission that the publication forms a part of the common general knowledge in the art, in Australia or any other country.

In the claims which follow and in the preceding description of the disclosure, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the disclosure.

### Legend

| | |
|---|---|
| 1 | Energy Storage System |
| 2 | Lead-in Cable |
| 3 | Distribution Cable |
| 4 | Load |
| 5 | External Grid |
| 6 | Additional Power Sources |
| 10 | Master Unit |
| 11 | Upper Zone |
| 12 | Intermediate Zone |
| 13 | Lower Zone |
| 14 | First Internal Divider |
| 15 | Second Internal Divider |
| 16 | Circuit Breaker Box |
| 17 | Inverter |
| 18 | Energy Storage Module |
| 19 | Plurality of Batteries Cells |
| 20 | BMS |
| 21 | Controller |
| 22 | Communications Module |
| 23 | First Junction Portion |
| 24 | Second Junction Portion |
| 25 | Front Bores (DC) |
| 26 | Rear Bores (AC) |
| 27 | Glands |
| 28 | Tubular Conduit |
| 29 | External Antenna |
| 30 | Housing |
| 31 | First Side Panel |
| 32 | Second Side Panel |
| 33 | Top Panel |
| 34 | Bottom Panel |
| 35 | Rear Panel |
| 36 | Front Panel |
| 37 | Upper Zone Plate |
| 38 | Intermediate Zone Plate |
| 38 | Lower Zone Plate |
| 40 | Magna Flap Aperture |
| 41 | Magna Flap Recess |
| 42 | Magna Flap Cover |
| 43 | Magna Flap Cover Tether |
| 44 | LED Indicator |
| 45 | Hidden Rear Mounting |
| | Aperture |
| 46 | Hollow Tubes |
| 47 | Glands |
| 48 | Mounting Bracket |
| 50 | Slave Unit |
| 51 | Slave Unit Casing |
| 52 | Upper Compartment |
| 53 | Intermediate Compartment |
| 54 | Lower Compartment |
| 55 | Additional Energy Storage |
| | Modules |
| 56 | Circuit Breaker |
| 57 | Junction Region |
| 58 | Front Bores (DC) |
| 101 | Energy Storage System |
| 110 | Main Unit |
| 111 | Upper Zone of Main Unit |
| 112 | Intermediate Zone of Main Unit |
| 113 | Lower Zone of Main Unit |
| 116 | Circuit Breaker of Main Unit |
| 117 | Inverter |
| 118 | Energy Storage Module |
| 121 | Controller |
| 122 | Communications Module |
| 123 | Junction Portions of Main Unit |
| 125 | Front Apertures of Junction Portion |
| 126 | Rear Bores of Junction Portion |
| 128 | Glands |
| 129 | External Antenna |
| 130 | Housing of Main Unit |
| 131 | First Side Panel of Main Unit Cover |
| 132 | Second Side Panel of Main Unit |
| | Cover |
| 133 | Top Panel of Main Unit Cover |
| 134 | Bottom Panel of Main Unit Cover |
| 135 | Backing Plate of Main Unit Cover |
| 136 | Front Panel of Main Unit Cover |
| 138 | Access Door of Main Unit |
| 148 | Mounting Bracket of Main Unit |
| 150 | Sub Unit |
| 151 | Sub Unit Casing |
| 152 | Upper Compartment of Sub Unit |
| 153 | Intermediate Compartment of Sub |
| | Unit |
| 154 | Lower Compartment of Sub Unit |
| 155 | Additional Energy Storage Modules |
| 156 | Circuit Breaker of Sub Unit |
| 157 | Junction Region of Sub Unit |
| 158 | Front Apertures of Sub Unit (DC) |
| 160 | Cover of Main Unit |
| 161 | Interior of Housing of Main Unit |
| 162 | First Mounting Surface of Main Unit |
| | Backing Plate |
| 163 | Second Mounting Surface of Main |
| | Unit Backing Plate |
| 164 | Mounting Holes of First Mounting |
| | Surface |
| 165 | Cavity of Second Mounting Surface |
| 166 | Rear portion of inverter |
| 167 | Aperture of Front Panel of Main |
| | Unit Cover |
| 168 | Ventilation Holes of Main Unit |
| | Cover |
| 169 | Peripheral lip of Main Unit Cover |
| 170 | Rubber Seal of Main Unit |
| 171 | Main Unit Mounting Bracket |
| | Engagement Members |
| 172 | Slots of Main Unit Housing |
| 173 | Main Unit Backing Plate Rails |
| 174 | Main Unit Access Door Magnets |
| 175 | Main Unit Removeable Cassette |
| 176 | Main Unit Touchscreen |
| 177 | Masking Plate of Cassette |
| 178 | Cover of Sub Unit |
| 179 | Backing Plate of Sub Unit |
| 180 | Interior of Sub Unit |
| 181 | Sub Unit Cassette |
| 182 | Sub Unit Access Door |
| 183 | Rectangular recess of side panels |
| 184 | Main-Sub Guide Plate |
| 185 | Mounting Bracket for Sub Unit |
| 186 | First receiving portion of main-sub |
| | Guide Plate |
| 187 | Second receiving portion of main- |
| | sub Guide Plate |
| 188 | Sub-Sub Guide Plate |
| 189 | First receiving portion of Sub-Sub |
| | Guide Plate |
| 190 | Second receiving portion of Sub- |
| | Sub Guide Plate |

1. A modular energy storage system for delivery of AC electrical power to a load, the energy storage system comprising a master unit; the master unit including an inverter, at least one storage module, a circuit breaker, a first junction portion, a second junction portion, and a housing having an interior divided into a first zone and a second zone; with the first zone containing the inverter for converting stored DC power within the storage module(s) to usable AC power for delivery to the load; the second zone containing the circuit breaker operatively connected to the first junction portion and the second junction portion; with each of the junction portions being configured to receive a lead-in cable coupling the energy storage system to an external power source and a distribution cable coupling the energy storage system to the load.

2. The modular energy storage system of claim 1, wherein the first junction portion is located on a first side of the housing and the second junction portion located on an opposing second side of the housing.

3. The modular energy storage system of claim 1, wherein the first and second zones are selectively sealable such that at least a portion of the second zone can be physically accessed whilst the first zone remains sealed.

4. (canceled)

5. The modular energy storage system of claim 1, wherein the housing comprises a rear panel with a mounting aperture, through which the housing can be secured to a wall by a fastener.

6. The modular energy storage system of claim 1, wherein the housing comprises a top panel configured such that when mounted to a wall, its surface is inclined with respect to the ground.

7. The modular energy storage system of claim 1, wherein the housing comprises a forward-facing panel including a separate cover plate for each of the first and second zones.

8. The modular energy storage system of claim 7, wherein the cover plate for the first zone incorporates an indicator to display information related to the energy storage system.

9. The modular energy storage system of claim 7, wherein the cover plate for first zone is attached to the housing with rearward facing fasteners and the cover plate for the second zone being removable attached to the housing with forward facing fasteners.

10. The modular energy storage system of claim 7, wherein the cover plate of the second zone includes a magnetically tethered flap proving tool-free access to the circuit breaker.

11. The modular energy storage system of claim 1, wherein the housing comprises an integral cover mountable to a backing plate, the cover being a shell having a front panel and side panels and a top and bottom panel integrated therewith.

12. The modular energy storage system of claim 11, wherein the backing plate has a stepped profile, the stepped profile providing a first mounting surface for components within the first zone, and a second mounting surface on a parallel plane offset from the first mounting surface, for components within the second zone.

13. The modular energy storage system of claim 12, wherein the first mounting surface has a recess for allowing a portion of the inverter to extend outwardly from the housing.

14. The modular energy storage system of claim 1, wherein the second zone of the master unit comprises an upper zone and a lower zone.

15. The modular energy storage system of claim 14, wherein the upper zone is selectively sealable from the lower zone such that the upper zone can be physically accessed whilst the lower zone remains sealed.

16. The modular energy storage system of claim 1, further comprising at least one slave unit to provide additional energy storage capacity.

17. The modular energy storage system of claim 16, wherein each of the junction portions provides an operable connection between the master unit and the at least one slave unit for additional energy storage capacity.

18. The modular energy storage system of claim 17, wherein the operable connection between the master unit and a slave unit includes glands to form a waterproof passage for connecting cables

19. The modular energy storage system of claim 16, wherein the slave unit includes at least one additional storage module, a second circuit breaker, a junction region and a casing having an interior divided into a first compartment and a second compartment; with the first compartment containing the additional storage module(s) providing the modular energy storage system with increased energy storage capacity; the second compartment containing the second circuit breaker operatively connected to the junction region; the junction region configured to facilitate an operative connection between the slave unit and the master unit.

20. The modular energy storage system of claim 19, wherein the slave unit further includes a second junction region, with each of the junction regions configured to provide an operative connection with an additional slave unit in a daisy-chain arrangement.

21. The modular energy storage system of claim 20, wherein the junction region is located on a first side of the casing and the second junction region is located on an opposing second side of the casing.

22-25. (canceled)
